(19) United States
(12) Patent Application Publication
(10) Pub. No.: US 2026/0032823 A1
(43) Pub. Date: Jan. 29, 2026

(54) MICROELECTRONIC DEVICES INCLUDING EMBEDDED ELECTRONIC COMPONENTS, AND ASSOCIATED METHODS AND SYSTEMS

(71) Applicant: Micron Technology, Inc., Boise, ID (US)

(72) Inventors: Kelvin Tan Aik Boo, Singapore (SG); Hong Wan Ng, Singapore (SG); Ling Pan, Singapore (SG); Chin Hui Chong, Singapore (SG); See Hiong Leow, Singapore (SG); Seng Kim Dalson Ye, Singapore (SG)

(21) Appl. No.: 19/247,291

(22) Filed: Jun. 24, 2025

Related U.S. Application Data
(60) Provisional application No. 63/675,166, filed on Jul. 24, 2024.

(51) Int. Cl. H05K 1/18; H05K 1/02; H05K 3/00; H05K 3/34

(52) U.S. Cl. CPC H05K 1/183; H05K 1/0256; H05K 3/0047; H05K 3/3452; H05K 2201/09909; H05K 2201/10234

(57) ABSTRACT

A microelectronic device includes a substrate and at least one conductive structure in the substrate. The microelectronic device further includes an electronic component at least partially embedded in the substrate. The electronic component coupled to the at least one conductive structure at a first end of the electronic component and vertically extending between the at least one conductive structure and a surface of the substrate. The microelectronic device also includes a conductive cap coupling a second end of the electronic component to a second conductive structure on a first surface of the substrate.

### CROSS-REFERENCE TO RELATED APPLICATION

This application claims the benefit under 35 U.S.C. § 119(e) of U.S. Provisional Patent Application Ser. No. 63/675, 166, filed Jul. 24, 2024, the disclosure of which is hereby incorporated herein in its entirety by this reference.

### TECHNICAL FIELD

Embodiments of the disclosure generally relate to microelectronic devices. In particular, embodiments of the disclosure relate to microelectronic devices including embedded electronic components, and associated method and systems.

### BACKGROUND

Microelectronic devices may include electronic components configured to perform different functions on electrons passing through the microelectronic devices, such as resisting the passage of the electrons, generating signals based on the passage of electrons, storing electrons, generating voltages based on the passage of electrons, changing connection paths based on the presence and/or passage of electrons, activating switches, among other functions. The electronic components may be coupled between conductive structures in the microelectronic devices, such that electrons may pass from one conductive structure to another through the electronic component where the electronic component performs the associated function on the electrons passing therethrough.

Microelectronic devices may be included in many different electronic devices and systems, such as computers, mobile phones, tablet computers, laptop computers, calculators, electronic control units, control boards, among others. As electronic devices and systems become more complex, circuit density of the associated microelectronic devices increases, which may lead to reductions in size of the microelectronic devices to maintain similar sizes for the associated electronic devices and/or to reduce the size of the associated electronic devices.

### BRIEF DESCRIPTION OF THE DRAWINGS

FIG. 1 illustrates a partial, vertical cross-sectional view of a microelectronic device, in accordance with embodiments of the disclosure;

FIG. 2 illustrates a partial, vertical cross-sectional view of a microelectronic device, in accordance with embodiments of the disclosure;

FIG. 3 illustrates a partial, vertical cross-sectional view of a microelectronic device, in accordance with embodiments of the disclosure;

FIG. 4 illustrates a partial, top-down view of the microelectronic device of FIG. 3;

FIGS. 5A-5F illustrate partial, vertical cross-sectional views of different process stages of a method of forming a microelectronic device, in accordance with embodiments of the disclosure; and

FIG. 6 is a schematic block diagram of an electronic system in accordance with one or more embodiments of the disclosure.

### DETAILED DESCRIPTION

The following description provides specific details, such as material compositions, shapes, and sizes, in order to provide a thorough description of embodiments of the disclosure. However, a person of ordinary skill in the art would understand that the embodiments of the disclosure may be practiced without employing these specific details. Indeed, the embodiments of the disclosure may be practiced in conjunction with conventional microelectronic device fabrication techniques employed in the industry. In addition, the description provided below does not form a complete process flow for manufacturing a microelectronic device (e.g., a memory device). The structures described below do not form a complete microelectronic device. Only those process acts and structures necessary to understand the embodiments of the disclosure are described in detail below. Additional acts to form a complete microelectronic device from the structures may be performed by conventional fabrication techniques.

Drawings presented herein are for illustrative purposes only and are not meant to be actual views of any particular material, component, structure, device, or system. Variations from the shapes depicted in the drawings as a result, for example, of manufacturing techniques and/or tolerances, are to be expected. Thus, embodiments described herein are not to be construed as being limited to the particular shapes or regions as illustrated, but include deviations in shapes that result, for example, from manufacturing. For example, a region illustrated or described as box-shaped may have rough and/or nonlinear features, and a region illustrated or described as round may include some rough and/or linear features. Moreover, sharp angles that are illustrated may be rounded, and vice versa. Thus, the regions illustrated in the figures are schematic in nature, and their shapes are not intended to illustrate the precise shape of a region and do not limit the scope of the present claims. The drawings are not necessarily to scale. Additionally, elements common between figures may retain the same numerical designation.

As used herein, a “memory device” means and includes microelectronic devices exhibiting memory functionality, but not necessarily limited to memory functionality. Stated another way, and by way of non-limiting example only, the term “memory device” includes not only conventional memory (e.g., conventional non-volatile memory; conventional volatile memory), but also includes an application specific integrated circuit (ASIC) (e.g., a system on a chip (SoC)), a microelectronic device combining logic and memory, and a graphics processing unit (GPU) incorporating memory.

As used herein the term “electronic components” means and includes any basic discrete electronic device or physical entity part of an electronic system used to affect electrons or their associated fields. An electronic component includes one or more terminals or leads configured to connect the electrical component to other electrical components and/or to conductive structures within a microelectronic device. An electronic component may include both passive components (e.g., resistors, inductors, capacitors, transformers) that affect electrons or their associated fields in the same manner regardless of any external electrical signals and active components (e.g., diodes, transistors, relays) that change how the electrons or their associated fields are affected based on an external electrical signal.

As used herein, the terms “configured” and “configuration” refers to a size, a shape, a material composition, a material distribution, orientation, and arrangement of at least one feature (e.g., one or more of at least one structure, at least one material, at least one region, at least one device) facilitating use of the at least one feature in a pre-determined way.

As used herein, the phrase “coupled to” refers to structures operatively connected with each other, such as electrically connected through a direct Ohmic connection or through an indirect connection (e.g., by way of another structure).

As used herein, the term “substantially” in reference to a given parameter means and includes to a degree that one skilled in the art would understand that the given parameter, property, or condition is met with a small degree of variance, such as within acceptable manufacturing tolerances. By way of example, depending on the particular parameter, property, or condition that is substantially met, the parameter, property, or condition may be at least 90.0 percent met, at least 95.0 percent met, at least 99.0 percent met, at least 99.9 percent met, or even 100.0 percent met.

As used herein, “about” or “approximately” in reference to a numerical value for a particular parameter is inclusive of the numerical value and a degree of variance from the numerical value that one of ordinary skill in the art would understand is within acceptable tolerances for the particular parameter. For example, “about” or “approximately” in reference to a numerical value may include additional numerical values within a range of from 90.0 percent to 110.0 percent of the numerical value, such as within a range of from 95.0 percent to 105.0 percent of the numerical value, within a range of from 97.5 percent to 102.5 percent of the numerical value, within a range of from 99.0 percent to 101.0 percent of the numerical value, within a range of from 99.5 percent to 100.5 percent of the numerical value, or within a range of from 99.9 percent to 100.1 percent of the numerical value.

As used herein, relational terms, such as “beneath,” “below,” “lower,” “bottom,” “above,” “upper,” “top,” “front,” “rear,” “left,” “right,” and the like, may be used for ease of description to describe one element's or feature's relationship to another element(s) or feature(s) as illustrated in the drawings. Unless otherwise specified, the spatially relative terms are intended to encompass different orientations of the materials in addition to the orientation depicted in the figures. For example, if materials in the figures are inverted, elements described as “below” or “beneath” or “under” or “on bottom of” other elements or features would then be oriented “above” or “on top of” the other elements or features. Thus, the term “below” can encompass both an orientation of above and below, depending on the context in which the term is used, which will be evident to one of ordinary skill in the art. The materials may be otherwise oriented (e.g., rotated 90 degrees, inverted, flipped) and the spatially relative descriptors used herein interpreted accordingly.

As used herein, the singular forms “a,” “an,” and “the” are intended to include the plural forms as well, unless the context clearly indicates otherwise.

As used herein, the term “and/or” means and includes any and all combinations of one or more of the associated listed items.

As used herein, the terms “vertical,” “longitudinal,” “horizontal,” and “lateral” are in reference to a major plane of a structure and are not necessarily defined by earth's gravitational field. A “horizontal” or “lateral” direction is a direction that is substantially parallel to the major plane of the structure, while a “vertical” or “longitudinal” direction is a direction that is substantially perpendicular to the major plane of the structure. The major plane of the structure is defined by a surface of the structure having a relatively large area compared to other surfaces of the structure. With reference to the drawings, a “horizontal” or “lateral” direction may be perpendicular to an indicated “Z” axis and may be parallel to an indicated “X” axis and/or parallel to an indicated “Y” axis; and a “vertical” or “longitudinal” direction may be parallel to an indicated “Z” axis, may be perpendicular to an indicated “X” axis, and may be perpendicular to an indicated “Y” axis.

As used herein, “conductive material” means and includes electrically conductive material such as one or more of a metal (e.g., tungsten (W), titanium (Ti), molybdenum (Mo), niobium (Nb), vanadium (V), hafnium (Hf), tantalum (Ta), chromium (Cr), zirconium (Zr), iron (Fe), ruthenium (Ru), osmium (Os), cobalt (Co), rhodium (Rh), iridium (Ir), nickel (Ni), palladium (Pd), platinum (Pt), copper (Cu), silver (Ag), gold (Au), aluminum (Al)), an alloy (e.g., a Co-based alloy, an Fe-based alloy, an Ni-based alloy, an Fe- and Ni-based alloy, a Co- and Ni-based alloy, an Fe- and Co-based alloy, a Co- and Ni-and Fe-based alloy, an Al-based alloy, a Cu-based alloy, a magnesium (Mg)-based alloy, a Ti-based alloy, a steel, a low-carbon steel, a stainless steel), a conductive metal-containing material (e.g., a conductive metal nitride, a conductive metal silicide, a conductive metal carbide, a conductive metal oxide), and a conductively-doped semiconductor material (e.g., conductively-doped polysilicon, conductively-doped germanium (Ge), conductively-doped silicon germanium (SiGe)). In addition, a “conductive structure” means and includes a structure formed of and including conductive material.

As used herein, “insulative material” means and includes electrically insulative material, such as one or more of at least one dielectric oxide material (e.g., one or more of a silicon oxide (SiOₓ), phosphosilicate glass, borosilicate glass, borophosphosilicate glass, fluorosilicate glass, an aluminum oxide (AlOₓ), a hafnium oxide (HfOₓ), a niobium oxide (NbOₓ), a titanium oxide (TiOₓ), a zirconium oxide (ZrOₓ), a tantalum oxide (TaOₓ), and a magnesium oxide (MgOₓ)), at least one dielectric nitride material (e.g., a silicon nitride (SiN_{y})), at least one dielectric oxynitride material (e.g., a silicon oxynitride (SiOₓN_{y})), at least one dielectric oxycarbide material (e.g., silicon oxycarbide (SiOₓC_{y})), at least one hydrogenated dielectric oxycarbide material (e.g., hydrogenated silicon oxycarbide (SiCₓO,H_{z})), and at least one dielectric carboxynitride material (e.g., a silicon carboxynitride (SiOₓC_{z}N_{y})). Formulae including one or more of “x,” “y,” and “z” herein (e.g., SiOₓ, AlOₓ, HfOₓ, NbOₓ, TiOₓ, SiN_{y}, SiOₓN_{y}, SiOₓC_{y}, SiCₓO_{y}H_{z}, SiOₓC_{z}N_{y}) represent a material that contains an average ratio of “x” atoms of one element, “y” atoms of another element, and “z” atoms of an additional element (if any) for every one atom of another element (e.g., Si, Al, Hf, Nb, Ti). As the formulae are representative of relative atomic ratios and not strict chemical structure, an insulative material may comprise one or more stoichiometric compounds and/or one or more non-stoichiometric compounds, and values of “x,” “y,” and “z” (if any) may be integers or may be non-integers. As used herein, the term “non-stoichiometric compound” means and includes a chemical compound with an elemental composition that cannot be represented by a ratio of well-defined natural numbers and is in violation of the law of definite proportions. In addition, an “insulative structure” means and includes a structure formed of and including insulative material.

As used herein, the term “semiconductor material” refers to a material having an electrical conductivity between those of insulative materials and conductive materials. For example, a semiconductor material may have an electrical conductivity of between about 10-8 Siemens per centimeter (S/cm) and about 10⁴ S/cm (10⁶ S/m) at room temperature. Examples of semiconductor materials include elements found in column IV of the periodic table of elements such as silicon (Si), germanium (Ge), and carbon (C). Other examples of semiconductor materials include compound semiconductor materials such as binary compound semiconductor materials (e.g., gallium arsenide (GaAs)), ternary compound semiconductor materials (e.g., Al_{X}Ga_{1-X}As), and quaternary compound semiconductor materials (e.g., Ga_{X}In_{1-X}As_{Y}P_{1-Y}), without limitation. Compound semiconductor materials may include combinations of elements from columns III and V of the periodic table of elements (III-V semiconductor materials) or from columns II and VI of the periodic table of elements (II-VI semiconductor materials), without limitation. Further examples of semiconductor materials include oxide semiconductor materials such as zinc tin oxide (ZnₓSn_{y}O, commonly referred to as “ZTO”), indium zinc oxide (InₓZn_{y}O, commonly referred to as “IZO”), zinc oxide (ZnₓO), indium gallium zinc oxide (InₓGa_{y}Zn_{z}O, commonly referred to as “IGZO”), indium gallium silicon oxide (InₓGa_{y}Si_{z}O, commonly referred to as “IGSO”), indium tungsten oxide (InₓW_{y}O, commonly referred to as “IWO”), indium oxide (InₓO), tin oxide (SnₓO), titanium oxide (TiₓO), zinc oxide nitride (ZnₓON_{z}), magnesium zinc oxide (MgₓZn_{y}O), zirconium indium zinc oxide (ZrₓIn_{y}Zn_{z}O), hafnium indium zinc oxide (HfₓIn_{y}Zn_{z}O), tin indium zinc oxide (SnₓIn_{y}Zn_{z}O), aluminum tin indium zinc oxide (AlₓSn_{y}In_{y}ZnₐO), silicon indium zinc oxide (SiₓIn_{y}Zn_{z}O), aluminum zinc tin oxide (AlₓZn_{y}Sn_{z}O), gallium zinc tin oxide (GaₓZn_{y}Sn_{z}O), zirconium zinc tin oxide (ZrₓZn_{y}Sn_{z}O), and other similar materials. In addition, each of a “semiconductor structure” and a “semiconductive structure” means and includes a structure formed of and including semiconductor material.

Formulae including one or more of “x,” “y,” and “z” herein (e.g., SiOₓ, AlOₓ, HfOₓ, NbOₓ, TiOₓ, SiN_{y}, SiOₓN_{y}, SiOₓC_{y}, SiCₓO_{y}H_{z}, SiOₓC_{z}N_{y}) represent a material that contains an average ratio of “x” atoms of one element, “y” atoms of another element, and “z” atoms of an additional element (if any) for every one atom of another element (e.g., Si, Al, Hf, Nb, Ti). As the formulae are representative of relative atomic ratios and not strict chemical structure, an insulative material may comprise one or more stoichiometric compounds and/or one or more non-stoichiometric compounds, and values of “x,” “y,” and “z” (if any) may be integers or may be non-integers. As used herein, the term “non-stoichiometric compound” means and includes a chemical compound with an elemental composition that cannot be represented by a ratio of well-defined natural numbers and is in violation of the law of definite proportions. In addition, an “insulative structure” means and includes a structure formed of and including insulative material.

As used herein, the term “homogeneous” means relative amounts of elements included in a feature (e.g., a material, a structure) do not vary throughout different portions (e.g., different horizontal portions, different vertical portions) of the feature. Conversely, as used herein, the term “heterogeneous” means relative amounts of elements included in a feature (e.g., a material, a structure) vary throughout different portions of the feature. If a feature is heterogeneous, amounts of one or more elements included in the feature may vary stepwise (e.g., change abruptly), or may vary continuously (e.g., change progressively, such as linearly, parabolically) throughout different portions of the feature. The feature may, for example, be formed of and include a stack of at least two different materials.

Unless the context indicates otherwise, the materials described herein may be formed by any suitable technique including, but not limited to, spin coating, blanket coating, chemical vapor deposition (CVD), plasma enhanced CVD (PECVD), atomic layer deposition (ALD), plasma enhanced ALD (PEALD), physical vapor deposition (PVD) (e.g., sputtering), or epitaxial growth. Depending on the specific material to be formed, the technique for depositing or growing the material may be selected by a person of ordinary skill in the art. In addition, unless the context indicates otherwise, removal of materials described herein may be accomplished by any suitable technique including, but not limited to, etching (e.g., dry etching, wet etching, vapor etching), ion milling, abrasive planarization (e.g., chemical-mechanical planarization (CMP)), or other known methods.

As electronic devices and systems become more complex, circuit density of the associated microelectronic devices increases, which may lead to reductions in size of the microelectronic devices to maintain similar sizes for the associated electronic devices and/or to reduce the size of the associated electronic devices. The microelectronic devices may include electronic components configured to perform different functions in the microelectronic devices. The electronic components may be between conductive structures in the microelectronic devices. The electronic components may have standard sizes, such that their inclusion in the microelectronic device defines space in the microelectronic device that cannot be reduced. Changes to how the electronic components are mounted to the microelectronic devices may facilitate a reduction in the horizontal area of the microelectronic device used by the electronic components while facilitating thinning of the microelectronic device as well.

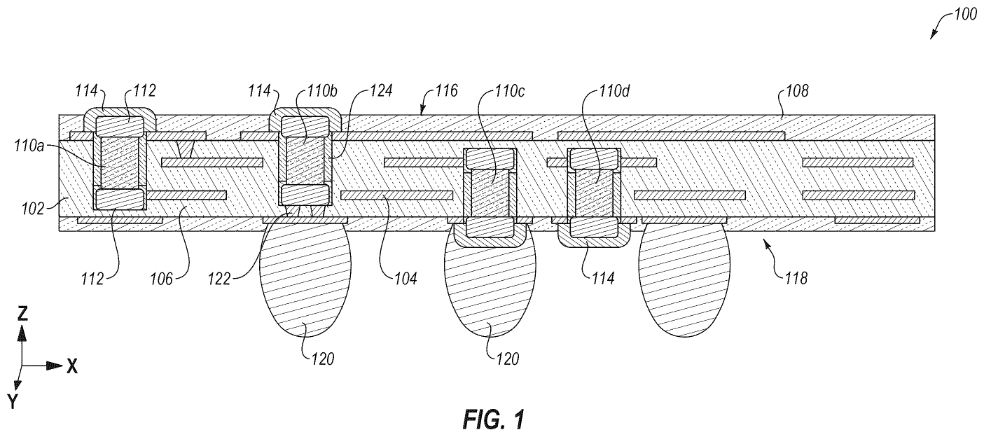

FIG. 1 illustrates a partial, vertical cross-sectional view of a microelectronic device 100 including a substrate 102 (e.g., a package substrate) formed from a dielectric structure 106 with embedded conductive structures 104. The conductive structures 104 may form conductive paths through the substrate 102 configured to form circuits and/or connect components, such as electronic components, contact pads, solder balls, and connection pins. The microelectronic device 100 may be configured as an integrated circuit (IC), a printed circuit board, control board, or a component thereof.

As shown in FIG. 1, the microelectronic device 100 may include multiple electronic components 110a, 110b, 110c, 110d disposed in the substrate 102. The electronic components 110a, 110b, 110c, 110d may have vertical orientations within the substrate 102, such that the longer dimension of the electronic components 110a, 110b, 110c, 110d extends in a vertical direction (e.g., a Z-direction). The vertical orientations of the electronic components 110a, 110b, 110c, 110d may reduce a lateral area of the microelectronic device 100 occupied by the electronic components 110a, 110b, 110c, 110d. For example, electronic components 110a, 110b, 110c, 110d formed according to Electronics Industries Alliance (EIA) Standard 01005 are about 0.4 mm by 0.2 mm; and electronic components 110a, 110b, 110c, 110d formed according to EIA Standard 0201 are about 0.6 mm by 0.3 mm. Therefore, arranging the electronic components 110a, 110b, 110c, 110d to have the longer dimension extending in the vertical direction may reduce the lateral area of the microelectronic device 100 used by the respective electronic components 110a, 110b, 110c, 110d by about one-half (0.5×).

Each of the electronic components 110a, 110b, 110c, 110d include two or more terminals 112 configured to couple the respective electronic components 110a, 110b, 110c, 110d to conductive structures 104 or other conductive elements of the microelectronic device 100.

For example, the electronic component 110a may have a first terminal 112 coupled to a conductive structure 104 embedded in the substrate 102, and a second terminal 112 coupled to a conductive cap 114 at an upper surface 116 of the microelectronic device 100 extending through a solder mask 108 of the microelectronic device 100. The conductive cap 114 may be configured to facilitate an external connection, such as a contact pad for connection to an external device or component.

In another example, the electronic component 110b may have a first terminal 112 coupled to a solder ball 120 extending from a lower surface 118 of the microelectronic device 100 through connecting structures 122, and a second terminal 112 coupled to a conductive cap 114 at the upper surface 116 of the microelectronic device 100 extending through the solder mask 108. The solder ball 120 may be configured to facilitate a connection between the electronic component 110b and an external device or component. The connecting structures 122 are conductive structures 104 extending vertically through the substrate 102 to facilitate a connection between the first terminal 112 of the electronic component 110b and the solder ball 120. The electronic component 110b may thus be connected between two separate external devices on opposing vertical sides of the microelectronic device 100 through the solder ball 120 on the first side of the electronic component 110b and the conductive cap 114 on the second side of the electronic component 110b. In FIG. 1, the electronic component 110b is coupled to the solder ball 120 through multiple connecting structures 122. In other embodiments, the multiple connecting structures 122 facilitate coupling multiple terminals 112 of the electronic component 110b to different conductive structures 104 within the microelectronic device 100. For example, if the electronic component 110b is a structure having three or more terminals 112, such as a transistor, the multiple connecting structures 122 together with the conductive cap 114 may facilitate three or more separate connections to the electronic component 110b.

In another example, the electronic component 110c may have a first terminal 112 coupled to a solder ball 120 extending from the lower surface 118, and a second terminal 112 coupled to a conductive structure 104 embedded in the substrate 102. The solder ball 120 may be configured to facilitate a connection between the electronic component 110c and an external device or component. In some embodiments, the electronic component 110c is connected to the solder ball 120 through a conductive cap 114.

In another example, the electronic component 110d may have a first terminal 112 coupled to a conductive cap 114 at the lower surface 118 of the microelectronic device 100 extending through a solder mask 108 of the microelectronic device 100, and a second terminal 112 coupled to a conductive structure 104 embedded in the substrate 102. The conductive cap 114 may be configured to facilitate a connection between the electronic component 110d and an external device or component. For example, the conductive cap 114 may be configured to facilitate an external connection, such as a contact pad for connection to an external device or component.

Each of the electronic components 110a, 110b, 110c, 110d may be substantially surrounded by an insulative fill 124 configured to substantially prevent the electronic components 110a, 110b, 110c, 110d from electrically connecting to surrounding conductive structures 104 that are not connected at one of the terminals 112 and/or to substantially prevent an electrical short between the terminals 112 of the electronic components 110a, 110b, 110c, 110d.

In some embodiments, a thickness of the microelectronic device 100 is greater than a length of the electronic components 110a, 110b, 110c, 110d. Connections may be formed through connecting structures 122 and/or conductive structures 104 to facilitate connections within the microelectronic device 100 when the microelectronic device 100 has a thickness greater than the length of the electronic components 110a, 110b, 110c, 110d.

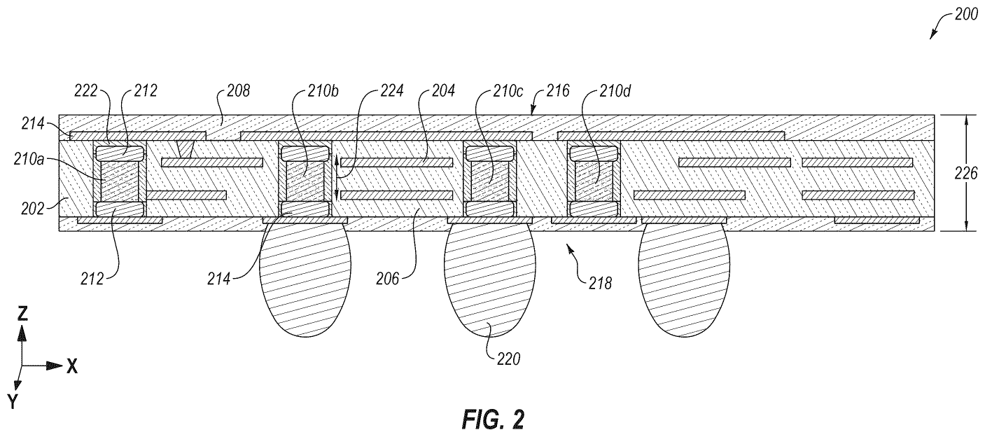

FIG. 2 illustrates a partial, vertical cross-sectional view of a microelectronic device 200, illustrating different arrangements of electronic components 210a, 210b, 210c, 210d within a substrate 202. Similar to the microelectronic device 100 of FIG. 1, the microelectronic device 200 includes a substrate 202 formed from a dielectric structure 206 with embedded conductive structures 204. The microelectronic device 200 may include electronic components 210a, 210b, 210c, 210d respectively vertically oriented and embedded in the substrate 202 of the microelectronic device 200. As illustrated in FIG. 2, the electronic components 210a, 210b, 210c, 210d may individually have a vertical height 224 (e.g., in the Z-direction) less than a vertical thickness 226 of the microelectronic device 200, such that the terminals 212 of the electronic components 210a, 210b, 210c, 210d are each positioned between the solder masks 208 that form an upper surface 216 and a lower surface 218 (e.g., outer surfaces) of the microelectronic device 200.

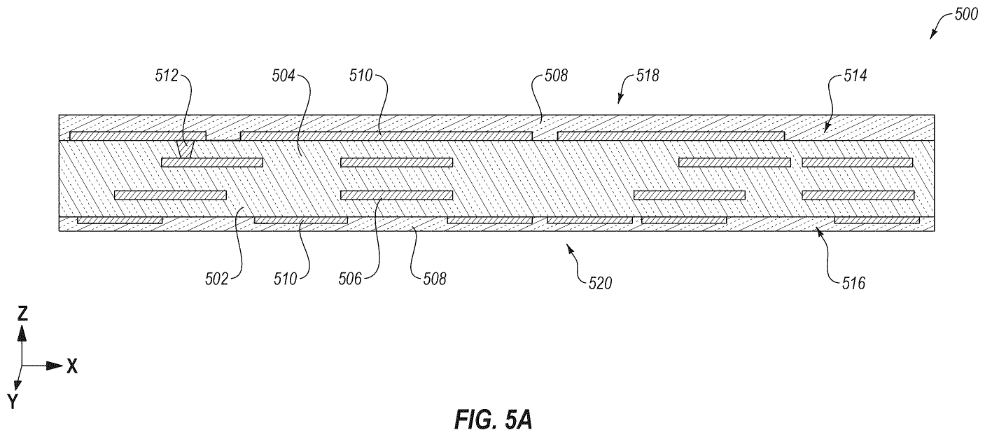

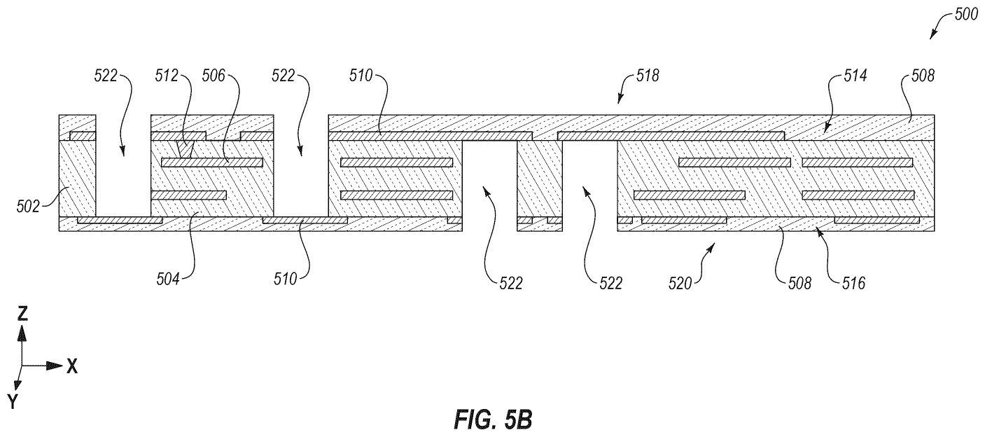

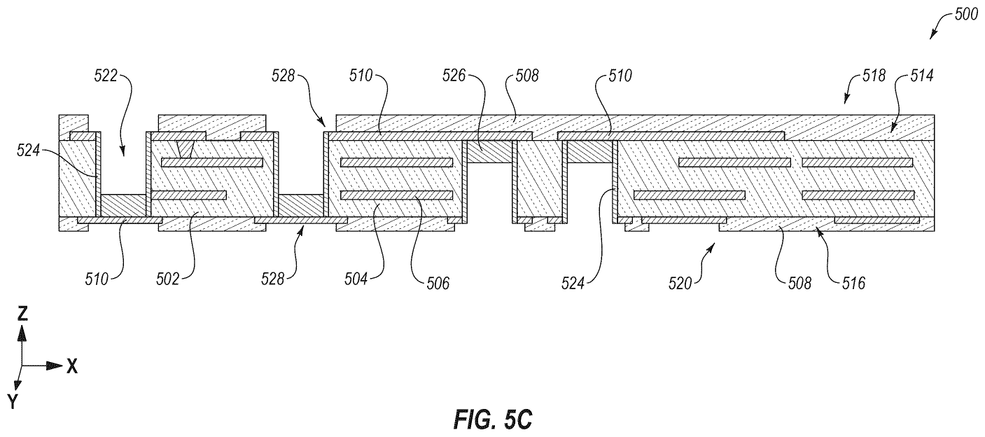

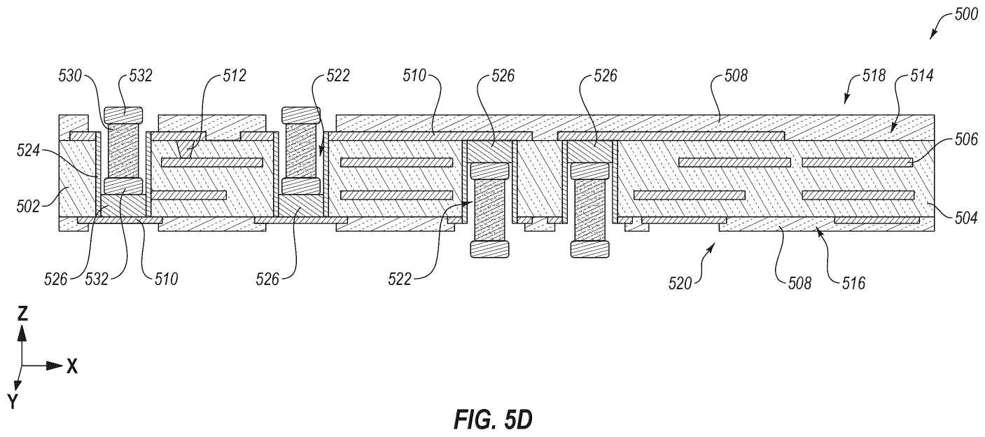

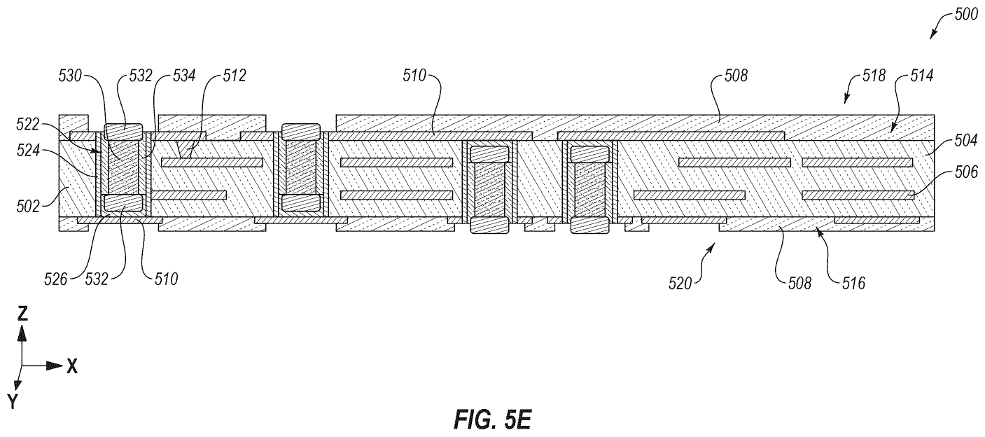

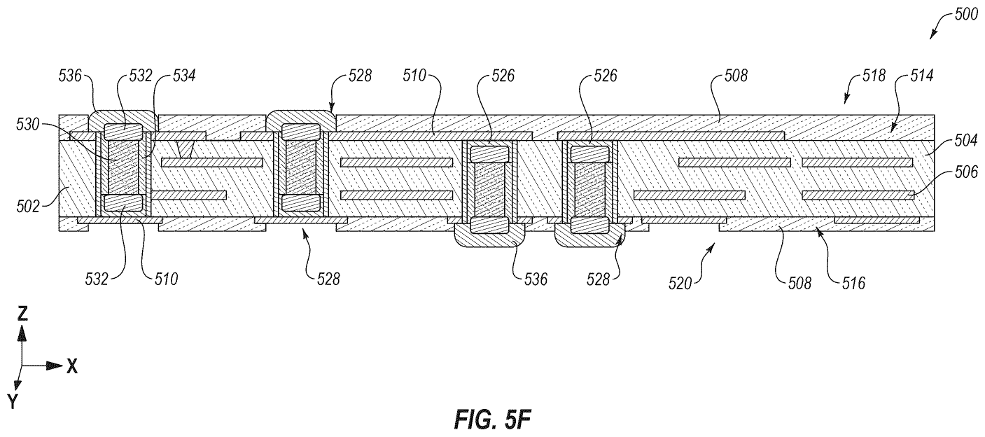

For example, the electronic component 210a may have a first terminal 212 coupled to a conductive surface structure 214 between the substrate 202 and the solder mask 208 proximate the lower surface 218 of the microelectronic device 200, and a second terminal 212 coupled to a conductive surface structure 214 between the substrate 202 and the solder mask 208 proximate the upper surface 216 of the microelectronic device 200. The second terminal 212 of the electronic component 210a may be coupled to the conductive surface structure 214 through a connecting structure 222. The connecting structure 222 may be a conductive structure formed during a reflow process after the electronic component 210a is installed, as discussed in further detail below with respect to FIG. 5A-FIG. 5F. For example, the connecting structure 222 may be a solder pad or solder fill substantially surrounding the second terminal 212 and filling in any space between the terminal 212 and the conductive surface structure 214 to form an electrical connection between the second terminal 212 and the conductive surface structure 214. As illustrated in FIG. 2, the electronic component 210a may not have any connections exposed through the solder mask 208 on the upper surface 216 or the lower surface 218 of the microelectronic device 200. Thus, the electronic component 210a may be configured to form an internal connection between one or more conductive paths or electronic devices of the microelectronic device 200.

In another example, the electronic component 210b may have a first terminal 212 coupled to a solder ball 220 extending from a lower surface 218 of the microelectronic device 200, and a second terminal 212 coupled to a conductive structure 204 embedded in the substrate 202 of the microelectronic device 200. The electronic component 210b may be connected to the solder ball 220 through a conductive surface structure 214 positioned vertically between the first terminal 212 and the solder ball 220 in an area between the substrate 202 and the solder mask 208 that forms the lower surface 218 of the microelectronic device 200. The solder ball 220 extends through the solder mask 208 and may be configured to facilitate a connection between the electronic component 210b and an external device or component.

In another example, the electronic component 210c may have a first terminal 212 coupled to a solder ball 220 extending from the lower surface 218, and a second terminal 212 coupled to a conductive surface structure 214 proximate the upper surface 216 of the microelectronic device 200 between the substrate 202 and the solder mask 208 that forms the upper surface 216 of the microelectronic device 200. The electronic component 210b may be connected to the solder ball 220 through a conductive surface structure 214 positioned vertically between the first terminal 212 and the solder ball 220 in an area between the substrate 202 and the solder mask 208 that forms the lower surface 218 of the microelectronic device 200. The solder ball 220 extends through the solder mask 208 and may be configured to facilitate a connection between the electronic component 210b and an external device or component.

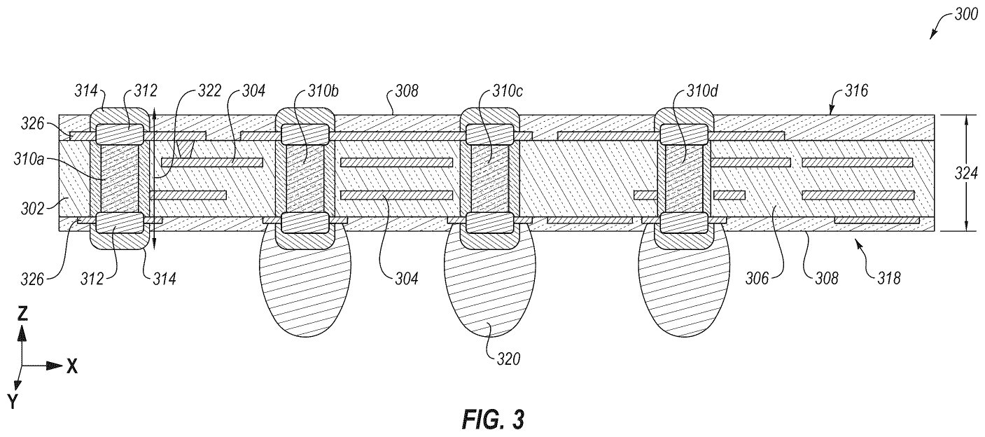

FIG. 3 illustrates a partial, vertical cross-sectional view of a microelectronic device 300, illustrating different arrangements of electronic components 310a, 310b, 310c, 310d within a substrate 302. Similar to the microelectronic devices 100, 200 of FIGS. 1 and 2, the microelectronic device 300 includes a substrate 302 formed from a dielectric structure 306 with embedded conductive structures 304. The microelectronic device 300 may include electronic components 310a, 310b, 310c, 310d vertically embedded in the substrate 302 of the microelectronic device 300. As shown in FIG. 3, the electronic components 310a, 310b, 310c, 310d may individually have a vertical height 322 (e.g., in the Z-direction) that is greater than a vertical thickness 324 of the microelectronic device 300, such that the terminals 312 of the electronic components 310a, 310b, 310c, 310d extend past at least one outer surface of the microelectronic device 300 (e.g., at least one of an upper surface 316 or a lower surface 318 of the microelectronic device 300).

For example, the electronic component 310a may have a first terminal 312 extending past the lower surface 318 of the microelectronic device 300, and a second terminal 312 extending out of the substrate 302 and into the vertical region of the solder mask 308 proximate the upper surface 316 of the microelectronic device 300. A conductive cap 314 may extend over each of the terminals 312. The conductive cap 314 may form an electrical connection between the respective terminal 312 and a conductive surface structure 326 positioned between the substrate 302 and the solder mask 308 as illustrated in FIG. 3. In other embodiments, the conductive cap 314 is configured to facilitate a connection between the electronic component 310a and an external device or component.

In another example, the electronic component 310b may have a first terminal 312 extending past the lower surface 318 of the microelectronic device 300, and a second terminal 312 extending out of the substrate 302 and into the vertical region of the solder mask 308 proximate the upper surface 316 of the microelectronic device 300. The first terminal 312 may be coupled to a solder ball 320 extending from the lower surface 318 of the microelectronic device 300. The electronic component 310b may be connected to the solder ball 320 through a conductive cap 314 extending over the first terminal 312. The solder ball 320 may be configured to facilitate a connection between the electronic component 310b and an external device or component. A conductive cap 314 extends over the second terminal 312. The conductive cap 314 may form an electrical connection between the second terminal 312 and a conductive surface structure 326 positioned between the substrate 302 and the solder mask 308 as illustrated in FIG. 3. In other embodiments, the conductive cap 314 is configured to facilitate a connection between the electronic component 310a and an external device or component.

In some embodiments, one or more of the electronic components 310a, 310b, 310c, 310d extend(s) past both the upper surface 316 and the lower surface 318 of the microelectronic device 300, such that both a first terminal 312 and a second terminal 312 extend vertically beyond the upper surface 316 and the lower surface 318 as defined by the solder mask 308. In some embodiments, one of the terminals 312 is fully embedded in the substrate 302, in a similar manner to the electronic components 110a, 110b, 110c, 110d described with reference to FIG. 1, for connection with a conductive structure 304 in the substrate 302 with the other of the terminals 312 extending a greater distance past the associated upper surface 316 or lower surface 318.

Electronic components 310a, 310b, 310c, 310d having a standard length that is greater than a thickness of a microelectronic device 300 may be vertically mounted in the microelectronic device 300 in the manner illustrated in FIG. 3. For example, a microelectronic device 300 may have thicknesses of less than about 0.4 mm. As discussed above, electronic components formed in accordance with the EIA Standard 0201 have a vertical height 322 of about 0.6 mm. Thus, at least one end of an electronic component formed according to EIA Standard 0201 would extend past the upper surface 316 or the lower surface 318 of a microelectronic device 300 having a thickness of less than about 0.4 mm.

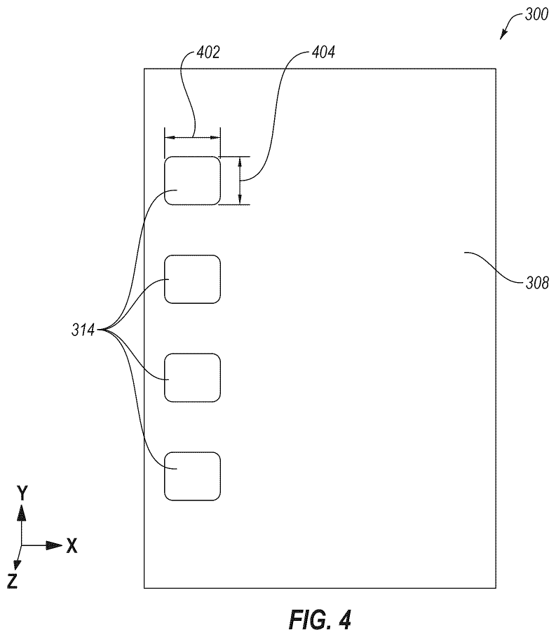

FIG. 4 illustrates a partial, top-down view of the microelectronic device 300 illustrated in FIG. 3. The upper surface 316 of the microelectronic device 300 may be formed by the solder mask 308. The conductive caps 314 may be exposed through the solder mask 308. As discussed above, the conductive caps 314 may be configured to provide a connection point for external devices or components.

The conductive caps 314 have a size defined by one or more major dimensions (e.g., diameter, radius, width, apothem). As shown in FIG. 4, the conductive caps 314 may have a rectangular horizontal cross-sectional shape defined by a width 402 in the X-direction and an additional width 404 in the Y-direction. As noted above, the widths 402, 404 may be defined by industry standards. For example, conductive caps 314 formed over electronic components 310a, 310b, 310c, 310d formed according to EIA Standard 01005 may have widths 402, 404 that are about 0.2 mm; and electronic components 310a, 310b, 310c, 310d formed according to EIA Standard 0201 may have widths 402, 404 that are about 0.3 mm. Other Standards may define other widths 402, 404.

In some embodiments, the widths 402, 404 are substantially the same, such that the conductive caps 314 have substantially square horizontal cross-sectional shapes. In other embodiments, the widths 402, 404 may be different lengths, such that the conductive caps 314 have different rectangular horizontal cross-sectional shapes.

FIGS. 5A-5F illustrate partial, vertical cross-sectional views of different process stages of a method of forming a microelectronic device 500. The microelectronic device 500 may be one of the microelectronic devices 100, 200, 300 described above with respect to FIGS. 1-4. The microelectronic device 500 is formed to include a substrate 502. The substrate 502 may be formed through a combination of building up material on a wafer, such as a silicon wafer, and removing material from the wafer and/or built up materials on the wafer. The materials may be built up on the wafer through any suitable technic including, but not limited to, spin coating, blanket coating, CVD, PECVD, ALD, PEALD, PVD (e.g., sputtering), epitaxial growth, or other methods. Material removal may be accomplished by any suitable process including, but not limited to, etching (e.g., dry etching, wet etching, vapor etching), ion milling, abrasive planarization (e.g., CMP), or other methods. For example, the substrate 502 may be formed by building up insulative structures 504, selectively removing portions of the insulative structures 504, and forming conductive structures 506 in the regions where the portions of the insulative structures 504 are removed.

The conductive structures 506 may be configured to facilitate conductive paths extending in lateral planes through the substrate 502 (e.g., in the X-direction and/or the Y-direction) and connecting structures 512 extending vertically through the substrate 502 (e.g., in the Z-direction). The connecting structures 512 may be configured to electrically connect conductive paths formed within different lateral planes (e.g., at different vertical levels) within the substrate 502. Some of the conductive structures 506 are formed as conductive surface structures 510 on an upper surface 514 and lower surface 516 of the substrate 502.

Solder masks 508 may be positioned over the upper surface 514 and the lower surface 516 of the substrate 502 and may form an upper surface 518 and a lower surface 520 (e.g., outer surfaces) of the microelectronic device 500. The solder masks 508 may be configured to protect the upper surface 514 and the lower surface 516 of the substrate 502. The solder masks 508 may be formed from an insulative material, such that electrical connections to the conductive surface structures 510 may be substantially controlled by the solder masks 508. For example, the solder masks 508 may be configured to substantially prevent external electrical connections to the conductive surface structures 510. Thus, electrical connections to the conductive surface structures 510 may be controlled by the controlled removal of portions of the solder masks 508.

Referring next to FIG. 5B, after the substrate 502 is formed and covered with the solder mask 508, recesses 522 may be formed to extend at least partially through the substrate 502. The recesses 522 may be formed through a material removal process, such as a mechanical drilling process or a laser drilling process. The material removal process may be configured to control a vertical depth of the recesses 522. In some embodiments, the recesses 522 vertically extend to a desired depth within the substrate 502, such as ending at a conductive structure 506 disposed within the insulative structure 504 of the substrate 502, similar to the recesses containing the electronic components 110a, 110b, 110c, 110d in FIG. 1. In other embodiments, the recesses 522 extend completely through the microelectronic device 500 forming a through hole, such as the recesses containing the electronic components 310a, 310b, 310c, 310d in FIG. 3.

As shown in FIG. 5B, the recesses 522 may extend to the conductive surface structures 510 on an opposite side of the substrate 502. For example, the recesses 522 formed to vertically extend from the upper surface 518 may vertically extend through the solder mask 508 on the upper surface 518 and through the substrate 502, and may end (e.g., terminate) at the lower surface 516 of the substrate 502. Such recesses 522 may expose the conductive surface structure 510 at the interface between the lower surface 516 of the substrate 502 and the solder mask 508 that forms the lower surface 520 of the microelectronic device 500, such that the conductive surface structure 510 forms lower boundaries of the recesses 522. As another example, the recesses 522 formed to vertically extend from the lower surface 520 may vertically extend through the solder mask 508 on the lower surface 520 and through the substrate 502, and may end (e.g., terminate) at the upper surface 514 of the substrate 502. Such recesses 522 may expose the conductive surface structure 510 formed at the interface between the upper surface 514 of the substrate 502 and the solder mask 508 that forms the upper surface 518 of the microelectronic device 500, such that the conductive surface structure 510 forms upper boundaries of the recesses 522.

Referring next to FIG. 5C, after forming the recesses 522, surfaces defining the recesses 522 may be lined with a liner material 524. The liner material 524 may be relatively thin metallic material (e.g., copper) formed (e.g., conformally deposited) on the surfaces defining the recesses 522. The liner material 524 may be formed through a plating process.

As shown in FIG. 5C, a solder balls 526 may be formed within remainders (e.g., unfilled portions) of the recesses 522. The solder balls 526 may respectively be configured to form an electrical connection between a terminal of an electronic component and a conductive structure 506 at a top end or a bottom end of respective recesses 522. For each recess 522 illustrated in FIG. 5C, the solder ball 526 therein may be configured to form an electrical connection between a terminal of an electronic component and a conductive surface structure 510 of the microelectronic device 500.

Portions of the conductive surface structures 510 may be exposed through openings 528 in the solder mask 508. For example, portions of the solder mask 508 corresponding to the recesses 522 may be removed to form openings 528 through the solder mask 508. As shown in FIG. 5C, the openings 528 correspond to open ends of the recesses 522 and are formed to have a relatively larger horizontal cross-sectional area than vertically underling portions of the recesses 522. Accordingly, sidewalls of portions of the conductive surface structures 510 through which the recesses 522 are formed may be exposed by the openings 528. In addition, portions of the solder mask 508 may be removed at an opposite side of the microelectronic device 500 by way of the open end of the recesses 522, exposing the conductive surface structures 510 defining the top ends or the bottom ends of associated recesses 522. The resulting openings 528 may expose the conductive surface structures 510 at sides of the conductive surface structures 510 opposite the recesses 522.

Referring next to FIG. 5D, after the solder balls 526 are formed within the lined recess 522, electronic components 530 may be provided within remainders of the recesses 522. A terminal 532 of each electronic component 530 may be positioned in contact with a respective solder ball 526 within a respective recess 522. A reflow process may be used to melt the solder ball 526 and form an electrical connection between the terminal 532 of the electronic component 530 and the associated conductive structure 506 of the substrate 502.

Referring next to FIG. 5E, after the solder balls 526 are melted, the terminals 532 of the electronic components 530 may be substantially surrounded by material of the solder balls 526. Thus, the material of the solder balls 526 may form an electrical connection between the associated terminals 532 and a conductive structure 506 of the substrate 502. The material of the solder balls 526 may also be configured to secure the associated electronic component 530 to the microelectronic device 500.

After the electronic components 530 are secured in place by melting the solder balls 526, remaining positions of the recesses 522 may be filled with insulative fill material 534. The insulative fill material 534 may be an insulative material, such as one or more of dielectric oxide material, dielectric nitride material, dielectric oxycarbide material, hydrogenated dielectric oxycarbide material, and dielectric carboxynitride material. The insulative fill material 534 may be configured to substantially prevent electrical shorts between two opposing terminals 532 of an individual electronic component by way of surrounding materials of the microelectronic device 500.

Referring next to FIG. 5F, the electronic components 530 may be further secured in place by conductive caps 536 positioned vertically over or under the electronic components 530. For example, the conductive caps 536 may be positioned on or over terminals 532 of the electronic components 530 that are exposed through the openings 528 in the solder masks 508. The conductive caps 536 may be positioned at least partially within and may at least partially fill the openings 528 extending through the solder masks 508.

The conductive caps 536 may be formed of and include conductive material, such as solder material. The conductive caps 536 may be configured to form an electrical connection between associated terminals 532 of the electronic components 530 and a respective one of the conductive surface structure 510. As discussed above, the openings 528 may be formed to have larger horizontal cross-sectional areas than horizontal cross-sectional areas of the recesses 522 associated therewith. Accordingly, portions of sidewalls of conductive surface structures 510 are exposed. The conductive caps 536 respectively form an electrical connection between an individual terminal 532 of the electronic component 530 within an individual recess 522 and the portion of sidewall of an individual conductive surface structure 510 defining an individual opening 528 associated with the recess 522.

In some embodiments, the conductive cap 536 is configured to facilitate a connection between the associated terminal 532 and an external device or component. In other examples, the conductive cap 536 serves as a base structure for another connecting structure, such as a solder ball (e.g., solder balls 120, 220, 320), a contact pad, a pin structure, or a socket structure.

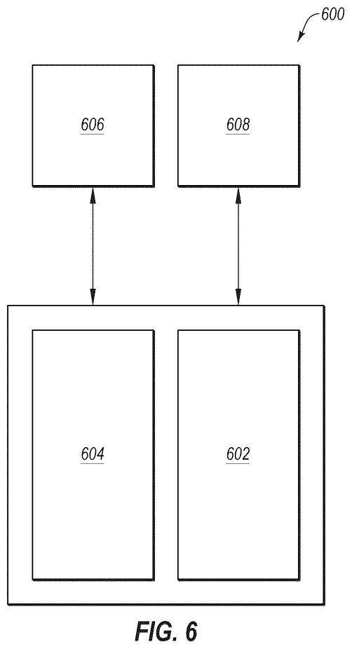

Microelectronic devices (e.g., the microelectronic devices 100, 200, 300, 500) may be included in embodiments of electronic systems of the disclosure. For example, FIG. 6 is a block diagram of an electronic system 600, in accordance with embodiments of the disclosure. The electronic system 600 may comprise, for example, a computer or computer hardware component, a server or other networking hardware component, a cellular telephone, a digital camera, a personal digital assistant (PDA), portable media (e.g., music) player, a Wi-Fi or cellular-enabled tablet such as, for example, an iPAD® or SURFACE® tablet, an electronic book, or a navigation device. The electronic system 600 includes at least one memory device 602. The memory device 602 may include, for example, an embodiment of a semiconductor device package including one or more of the microelectronic devices previously described herein (e.g., the microelectronic devices 100, 200, 300, 500 previously described with reference to FIGS. 1 through 5F).

The electronic system 600 may further include at least one electronic signal processor device 604 (often referred to as a “microprocessor”). The electronic signal processor device 604 may, optionally, include an embodiment of one or more of a microelectronic device and a microelectronic device structure previously described herein (e.g., the microelectronic devices 100, 200, 300, 500 previously described with reference to FIGS. 1 through 5F). The electronic system 600 may further include one or more input devices 606 for inputting information into the electronic system 600 by a user, such as, for example, a mouse or other pointing device, a keyboard, a touchpad, a button, or a control panel. The electronic system 600 may further include one or more output devices 608 for outputting information (e.g., visual or audio output) to a user such as, for example, a monitor, a display, a printer, an audio output jack, or a speaker. In some embodiments, the input device 606 and the output device 608 may comprise a single touchscreen device that can be used both to input information to the electronic system 600 and to output visual information to a user. The input device 606 and the output device 608 may communicate electrically (e.g., be operably connected) with one or more of the memory device 602 and the electronic signal processor device 604.

Thus, embodiments of the disclosure include a microelectronic device. The microelectronic device includes a substrate and at least one conductive structure in the substrate. The microelectronic device further includes an electronic component at least partially embedded in the substrate. The electronic component coupled to the at least one conductive structure at a first end of the electronic component and vertically extending between the at least one conductive structure and a surface of the substrate. The microelectronic device also includes a conductive cap coupling a second end of the electronic component to a second conductive structure on a first surface of the substrate.

Other embodiments of the disclosure include a method of forming a microelectronic device. The method includes forming a substrate including an insulative material and a conductive structure embedded within the insulative material. The method further includes forming a recess through a first surface of the substrate to expose at least a portion of the conductive structure. The method also includes disposing an electronic component within the recess. The method further includes coupling a first end of the electronic component to the conductive structure. The method also includes forming a conductive cap over a second end of the electronic component at the first surface of the substrate.

Another embodiment of the disclosure includes an electronic system. The system includes an input device, an output device, a processor device operably coupled to the input device and the output device, and a memory device operably coupled to the processor device. At least one of the memory device and the processor device includes a microelectronic device. The microelectronic device includes an insulative structure. The microelectronic device further includes a first solder mask over a first surface of the insulative structure. The microelectronic device also includes a second solder mask over a second surface of the insulative structure opposite the first surface. The microelectronic device further includes a first conductive surface structure between the first surface of the insulative structure and the first solder mask. The microelectronic device also includes a second conductive surface structure between the second surface of the insulative structure and the second solder mask. The microelectronic device further includes a vertically oriented electronic component disposed within the insulative structure, the vertically oriented electronic component comprising a first terminal electrically coupled to the first conductive surface structure and a second terminal electrically coupled to the second conductive surface structure.

Embodiments of the disclosure may facilitate reducing a lateral area of a microelectronic device used by electronic components without reducing the size or number of the electronic components. Reducing the lateral area of a microelectronic device used by the electronic components may facilitate increasing circuit density of the microelectronic device and/or reducing size requirements of larger electronic devices and/or systems using the microelectronic device. Reducing size requirements of larger electronic devices and/or systems may facilitate increasing the circuit density of the larger electronic device or system and/or reducing the size of the larger electronic device or system.

The embodiments of the disclosure described above and illustrated in the accompanying drawing figures do not limit the scope of the invention, since these embodiments are merely examples of embodiments of the invention, which is defined by the appended claims and their legal equivalents. Any equivalent embodiments are intended to be within the scope of this disclosure. Indeed, various modifications of the present disclosure, in addition to those shown and described herein, such as alternative useful combinations of the elements described, may become apparent to those skilled in the art from the description. Such modifications and embodiments are also intended to fall within the scope of the appended claims and their legal equivalents.

1. A microelectronic device comprising:
a substrate comprising:
at least one conductive structure in the substrate;
an electronic component at least partially embedded in the substrate, the electronic component coupled to the at least one conductive structure at a first end of the electronic component and vertically extending between the at least one conductive structure and a surface of the substrate; and
a conductive cap coupling a second end of the electronic component to a second conductive structure on a first surface of the substrate.

2. The microelectronic device of claim 1, wherein the at least one conductive structure is on a second surface of the substrate opposite the first surface of the substrate.

3. The microelectronic device of claim 1, wherein the at least one conductive structure is disposed within the substrate.

4. The microelectronic device of claim 1, wherein the at least one conductive structure includes at least one connecting structure extending vertically through the substrate between at least two conductive structures extending in two different lateral planes within the substrate.

5. The microelectronic device of claim 4, wherein at least one of the at least two conductive structures comprises a solder ball coupling a terminal at the first end of the electronic component to the at least one connecting structure.

6. The microelectronic device of claim 1, wherein the electronic component comprises:
a first terminal coupled to the at least one conductive structure; and
a second terminal coupled to the conductive cap.

7. The microelectronic device of claim 1, further comprising an insulative material substantially surrounding the electronic component between the first end of the electronic component and the second end of the electronic component.

8. The microelectronic device of claim 1, further comprising a solder mask defining an upper surface of the microelectronic device.

9. The microelectronic device of claim 8, wherein the second end of the electronic component is within vertical boundaries of the solder mask.

10. The microelectronic device of claim 8, wherein the second end of the electronic component overlies the upper surface of the microelectronic device.

11. A method of forming a microelectronic device, the method comprising:
forming a substrate including an insulative material and a conductive structure embedded within the insulative material;
forming a recess through a first surface of the substrate to expose at least a portion of the conductive structure;
disposing an electronic component within the recess;
coupling a first end of the electronic component to the conductive structure; and
forming a conductive cap over a second end of the electronic component at the first surface of the substrate.

12. The method of claim 11, wherein forming the conductive cap over the second end of the electronic component comprises coupling the second end of the electronic component to a conductive surface structure of the substrate through the conductive cap.

13. The method of claim 11, wherein coupling the first end of the electronic component to the conductive structure comprises melting a solder ball disposed in the recess, the solder ball forming an electrical connection between the first end of the electronic component and the conductive structure.

14. The method of claim 11, further comprising filling a remainder of the recess with insulative material such that the insulative material substantially surrounds the electronic component.

15. The method of claim 11, further comprising forming an opening in a solder mask overlying the substrate, the opening in the solder mask vertically overlying and horizontally overlapping the recess and having horizontal cross-sectional area greater than that of the recess.

16. The method of claim 15, wherein forming the conductive cap comprises forming the conductive cap within the horizontal cross-sectional area of the opening in the solder mask.

17. An electronic system comprising:
an input device;
an output device;
a processor device operably coupled to the input device and the output device; and
a memory device operably coupled to the processor device;
at least one of the memory device and the processor device comprising a microelectronic device comprising:
an insulative structure;
a first solder mask over a first surface of the insulative structure;
a second solder mask over a second surface of the insulative structure opposite the first surface;
a first conductive surface structure between the first surface of the insulative structure and the first solder mask;
a second conductive surface structure between the second surface of the insulative structure and the second solder mask; and
a vertically oriented electronic component disposed within the insulative structure, the vertically oriented electronic component comprising a first terminal electrically coupled to the first conductive surface structure and a second terminal electrically coupled to the second conductive surface structure.

18. The electronic system of claim 17, wherein the first terminal of the vertically oriented electronic component is electrically coupled to the first conductive surface structure through a conductive cap formed over the first terminal.

19. The electronic system of claim 17, wherein at least one of the first terminal and the second terminal of the vertically oriented electronic component extends past an outer surface of the microelectronic device defined by one of the first solder mask and the second solder mask.

20. The electronic system of claim 17, the microelectronic device further including a filled recess defined between the first surface and the second surface, the vertically oriented electronic component disposed within boundaries of the filled recess and an insulative fill material substantially surrounding the electronic component within the filled recess.
